(19) United States
(12) Patent Application Publication
(10) Pub. No.: US 2021/0278611 A1
(43) Pub. Date: Sep. 9, 2021

(54) METHODS OF FORMING A V-GROOVE FOR A FIBER OPTICS CABLE ON AN INTEGRATED PHOTONICS CHIP

(71) Applicant: GLOBALFOUNDRIES U.S. Inc., Santa Clara, CA (US)

(72) Inventors: Asli Sahin, Danbury, CT (US); Colleen Meagher, Beacon, NY (US); Thomas Houghton, Marlboro, NY (US); Bo Peng, Sharon, MA (US); Karen Nummy, Newburgh, NY (US); Javier Ayala, Poughkeepsie, NY (US); Yusheng Bian, Ballston, NY (US)

(21) Appl. No.: 16/807,811

(22) Filed: Mar. 3, 2020

(51) Int. Cl. G02B 6/42; H01L 21/84; H01L 21/311

(52) U.S. Cl. CPC G02B 6/4243; H01L 21/31111; H01L 21/84; G02B 6/423

(57) ABSTRACT

One illustrative device disclosed herein includes a V-groove in a base semiconductor layer of a semiconductor-on-insulator (SOI) substrate, wherein the V-groove is adapted to have a fiber optics cable positioned therein, and an optical component positioned above the V-groove. The device also includes a first layer of silicon dioxide positioned above the optical component, a second layer of silicon dioxide positioned on and in contact with the first layer of silicon dioxide and a third layer of silicon dioxide positioned on and in contact with the second layer of silicon dioxide.

### BACKGROUND

### Field of the Invention

The present disclosure generally relates to various novel methods of forming a V-groove for a fiber optics cable on an integrated photonics chip and the resulting integrated circuit (IC) product.

### Description of the Related Art

A need for greater bandwidth in fiber optic network links is widely recognized. The volume of data transmissions has seen a dramatic increase in the last decade. This trend is expected to grow exponentially in the near future. As a result, there exists a need for deploying an infrastructure capable of handling this increased volume and for improvements in system performance. Fiber optics communications have gained prominence in telecommunications, instrumentation, cable TV, network, and data transmission and distribution.

Photonics chips are used in many applications. A photonics chip integrates optical components, such as waveguides, couplers, photodetectors, etc., and electronic components, such as integrated circuits comprised of CMOS-based field-effect transistors, into a unified platform. The optical components must generally be able to perform at least the functions of light coupling, light propagation, light absorption and conversion of light to an electrical current. The optical components are formed in a photonics region of the product while the CMOS-based integrated circuits are formed in a CMOS region of the product.

In the CMOS region of an integrated circuit product that includes both optical components and CMOS-based integrated circuits, various FEOL (front-end-of-line) processing activities and structures (e.g., transistors, capacitors, resistors, etc.) are formed in the CMOS region, but such FEOL structures are not formed in the photonics region. Additionally, various BEOL (back-end-of-line) structures, (e.g., the individual conductive lines, the individual conductive vias, the individual layers of insulating material and individual etch stop layers) are formed in the CMOS region. In IC products that include both optical components and CMOS-based integrated circuits, the photonics region is substantially free of individual conductive lines and individual conductive vias similar to those formed in the CMOS region. However, the various BEOL layers of insulating material and BEOL etch stop layers that were formed in the CMOS region will also be formed in the photonics region. Ultimately, the BEOL layers of insulating material and BEOL etch stop layers in the photonics region will be removed and replaced with refractive index matching insulating material(s) to ensure optimal optical performance of the device.

The present disclosure is generally directed to various novel methods of forming a V-groove for a fiber optics cable on an integrated photonics chip and the resulting IC product.

### SUMMARY

The following presents a simplified summary of the invention in order to provide a basic understanding of some aspects of the invention. This summary is not an exhaustive overview of the invention. It is not intended to identify key or critical elements of the invention or to delineate the scope of the invention. Its sole purpose is to present some concepts in a simplified form as a prelude to the more detailed description that is discussed later.

The present disclosure is directed to various novel embodiments of forming a V-groove for a fiber optics cable on an integrated photonics chip and the resulting IC product. One illustrative device disclosed herein includes a V-groove in a base semiconductor layer of a semiconductor-on-insulator (SOI) substrate, wherein the V-groove is adapted to have a fiber optics cable positioned therein, and an optical component positioned above the V-groove. The device also includes a first layer of silicon dioxide positioned above the optical component, a second layer of silicon dioxide positioned on and in contact with the first layer of silicon dioxide and a third layer of silicon dioxide positioned on and in contact with the second layer of silicon dioxide.

### BRIEF DESCRIPTION OF THE DRAWINGS

The disclosure may be understood by reference to the following description taken in conjunction with the accompanying drawings, in which like reference numerals identify like elements, and in which:

FIGS. 1-19 depict various novel methods of forming a V-groove for a fiber optics cable on an integrated photonics chip and the resulting IC product. The drawings are not to scale.

While the subject matter disclosed herein is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION

Various illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming but would nevertheless be a routine undertaking for those of ordinary skill in the art having the benefit of this disclosure.

The present subject matter will now be described with reference to the attached figures. Various structures, systems and devices are schematically depicted in the drawings for purposes of explanation only and so as to not obscure the present disclosure with details that are well known to those skilled in the art. Nevertheless, the attached drawings are included to describe and explain illustrative examples of the present disclosure. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase. As will be readily apparent to those skilled in the art upon a complete reading of the present application, the presently disclosed method may be applicable to a variety of products, including, but not limited to, logic products, memory products, etc. With reference to the attached figures, various illustrative embodiments of the methods and devices disclosed herein will now be described in more detail. The various components, structures and layers of material depicted herein may be formed using a variety of different materials and by performing a variety of known process operations, e.g., chemical vapor deposition (CVD), atomic layer deposition (ALD), a thermal growth process, spin-coating techniques, masking, etching, etc. The thicknesses of these various layers of material may also vary depending upon the particular application.

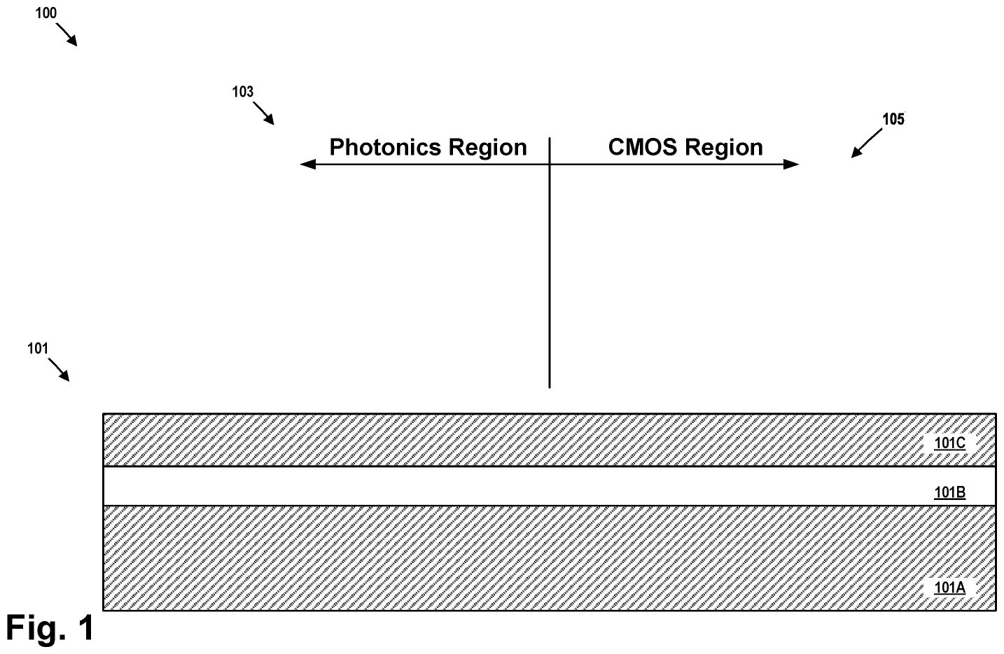

FIGS. 1-19 depict various novel methods of forming a V-groove for a fiber optics cable on an integrated photonics chip and the resulting IC product 100. Photonics chips are used in many applications. A photonics chip integrates optical components, such as waveguides, couplers, photodetectors, etc., and electronic components, such as integrated circuits comprised of CMOS-based field-effect transistors, into a unified platform. The optical components are adapted to perform at least the functions of light coupling, light propagation, light absorption and conversion of light to an electrical current, i.e., photocurrent.

With reference to FIG. 1, the IC product 100 or photonics chip will be formed above a semiconductor substrate 101. The IC product 100 comprises a photonics region 103—where optical components will be formed—and a CMOS region 105—where CMOS-based integrated circuits based upon NFET and PFET transistors will be formed. The substrate 101 may have a variety of configurations, such as a semiconductor-on-insulator (SOI) shown in FIG. 1. Such an SOI substrate 101 includes a base semiconductor layer 101A, a buried insulation layer 101B positioned on the base semiconductor layer 101A and an active semiconductor layer 101C positioned above the buried insulation layer 101B, wherein the optical components and the CMOS-based integrated circuits will be formed in and above the active semiconductor layer 101C. The thickness of the active semiconductor layer 101C and the buried insulation layer 101B may vary depending upon the particular application. The active semiconductor layer 101C and the base semiconductor layer 101A need not be made of the same semiconductor material, but that may be the case in some applications. In some applications, the active semiconductor layer 101C and the base semiconductor layer 101A may be made of silicon or they may be made of semiconductor materials other than silicon. Thus, the terms “substrate” or “semiconductor substrate” should be understood to cover all semiconductor materials and all forms of such materials. The buried insulation layer 101B may comprise any desired insulating material, e.g., USG (undoped silicate glass) silicon dioxide, etc.

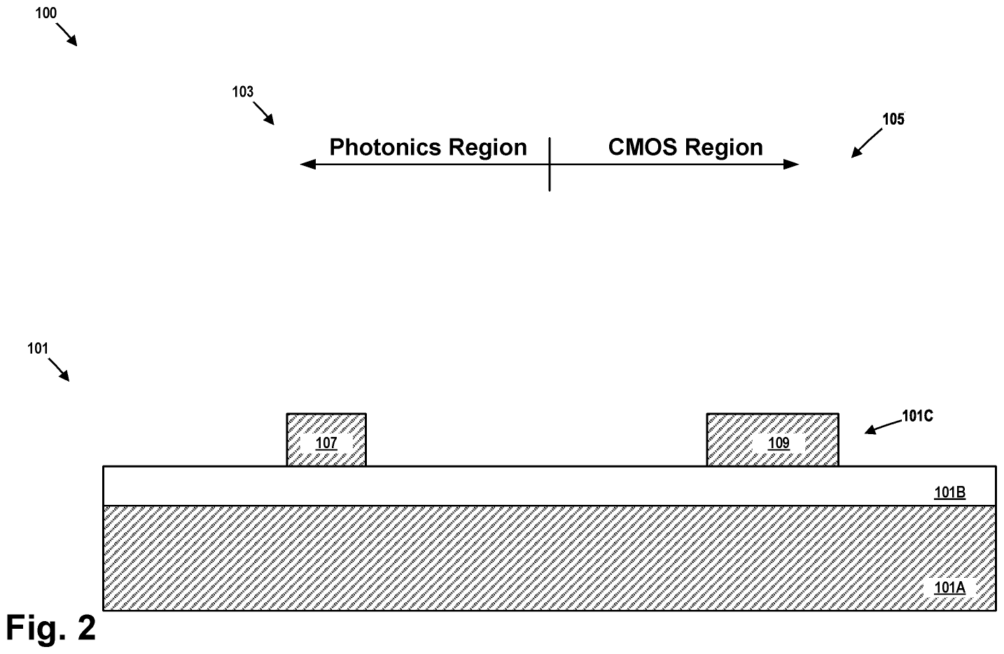

FIG. 2 depicts the IC product 100 after several process operations were performed in accordance with one illustrative process flow. In this example, an illustrative and simplistically depicted optical component 107, e.g., a waveguide, a light coupler, a photodetector, etc., was formed in the photonics region 103 by etching the active semiconductor layer 101C using known masking and etching techniques. In some applications, additional semiconductor material may be formed above the active semiconductor layer 101C prior to performing such an etching process to form the illustrative optical component 107. Additionally, the active semiconductor layer 101C in the CMOS region 105 was etched to form an active region 109 above which at least one transistor (not shown) is formed using known masking and etching techniques. The optical component 107 and the active region 109 may, in some embodiments, be formed by performing one or more etching processes through a single patterned etch mask (not shown). In other applications, the optical component 107 and the active region 109 may be formed by forming separate patterned etch masks and separate etching steps. In the illustrative example depicted herein, the upper surfaces of the optical component 107 and the active region 109 are depicted as being at approximately the same level so as to facilitate explanation of the subject matter disclosed herein. In other cases (not shown), the upper surface of the optical component 107 may be positioned a greater distance above the base semiconductor layer 101A than the upper surface of the active region 109.

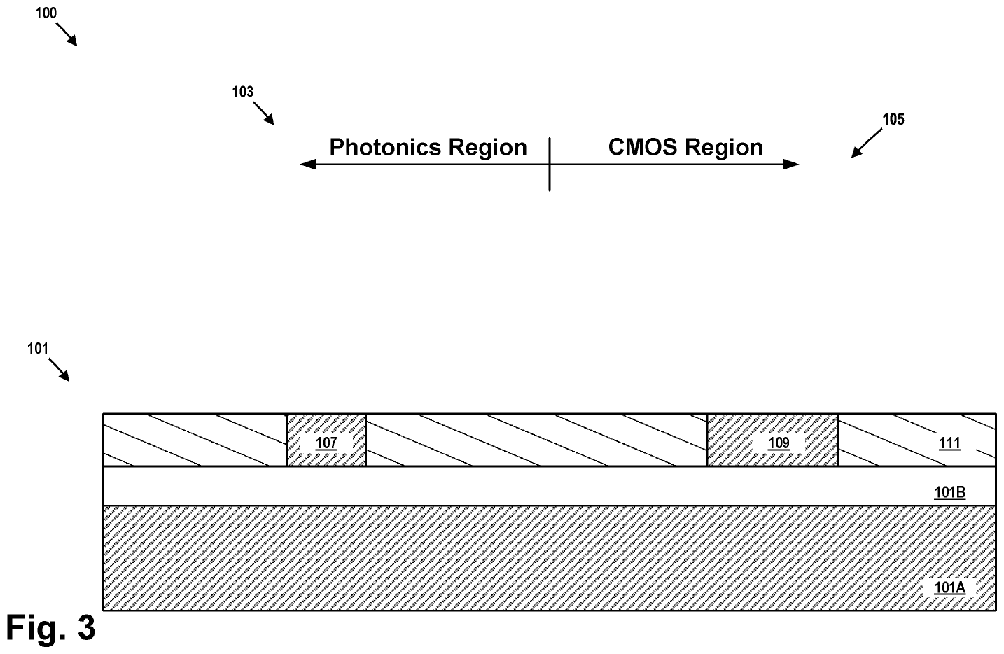

FIG. 3 depicts the IC product 100 after several process operations were performed. First, a layer of insulating material 111, e.g., USG (undoped silicate glass) silicon dioxide, etc., was blanket deposited on the product 100 so as to over-fill the spaces (or trenches) between the optical component 107 and the active region 109. Thereafter, a planarization process, e.g., a chemical mechanical planarization (CMP) and/or an etch-back process, was performed to planarize the upper surface of the layer of insulating material 111 with the upper surface of the optical component 107 and the upper surface of the active region 109.

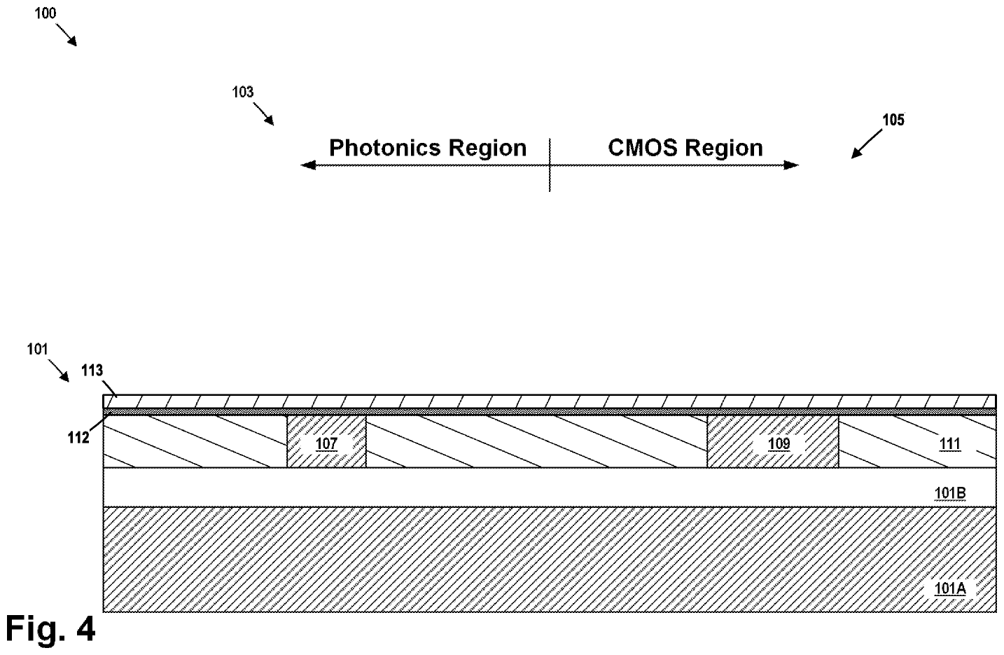

FIG. 4 depicts the IC product 100 after several process operations were performed. First, a layer of insulating 112 was deposited across the substrate 101 in both the photonics region 103 and the CMOS region 105. Thereafter, a layer of insulating material 113 was formed above the layer on insulating material 112 in both the photonics region 103 and the CMOS region 105. In one illustrative embodiment, the layer of insulating material 112 may be comprised of silicon dioxide, USG silicon dioxide, etc. and it may have a thickness of about 1-100 nm. In one illustrative embodiment, the layer of insulating material 113 may be comprised of silicon nitride and it may have a thickness of about 1-150 nm. In one particularly illustrative example, the layer of insulating material 112 was formed on and in contact with an upper surface of the optical component 107 and the layer of insulating material 113 was formed on and in contact with the upper surface of the layer of insulating material 112.

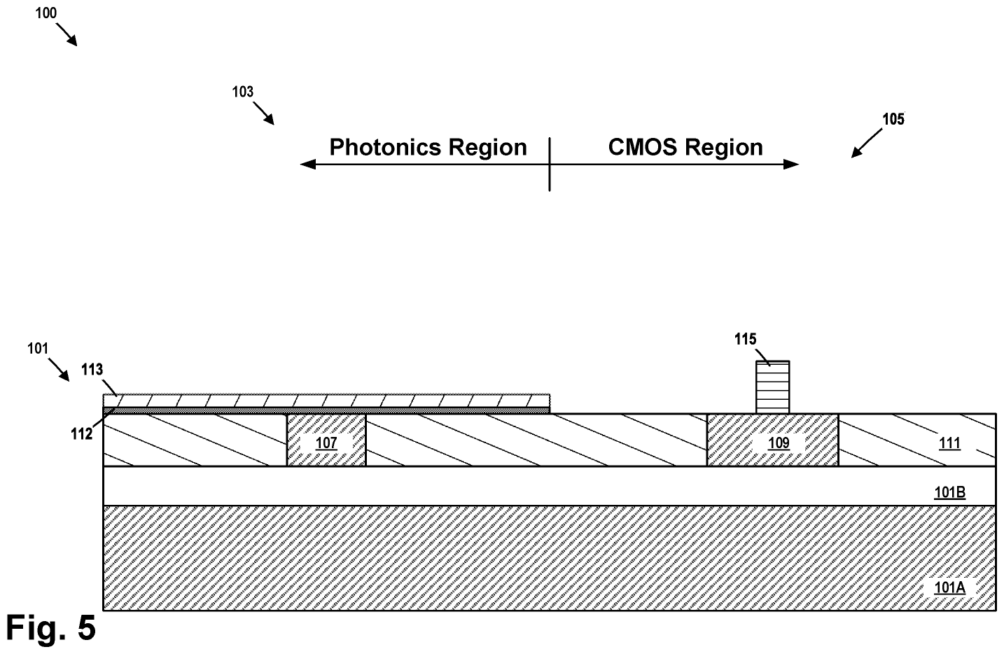

FIG. 5 depicts the IC product 100 after an illustrative and simplistically depicted gate structure 115 for a transistor device was formed above the active region 109 in the CMOS region 105. The photonics region 103 of the IC product 100 was masked during the various process operations performed to form the gate structure 115. In one illustrative example, the portion of the layers of insulating material 113 and 112 in the CMOS region 105 may be intentionally removed and/or inadvertently consumed during the performance of various process operations to form the CMOS-based circuits in the CMOS region 105. To the extent that any portions of the layers of insulating material 113, 112 remain in the CMOS region 105, they are not relevant to the particular subject matter disclosed herein. Thus, the remaining drawings do not depict the layers of insulating material 113, 112 in the CMOS region 105.

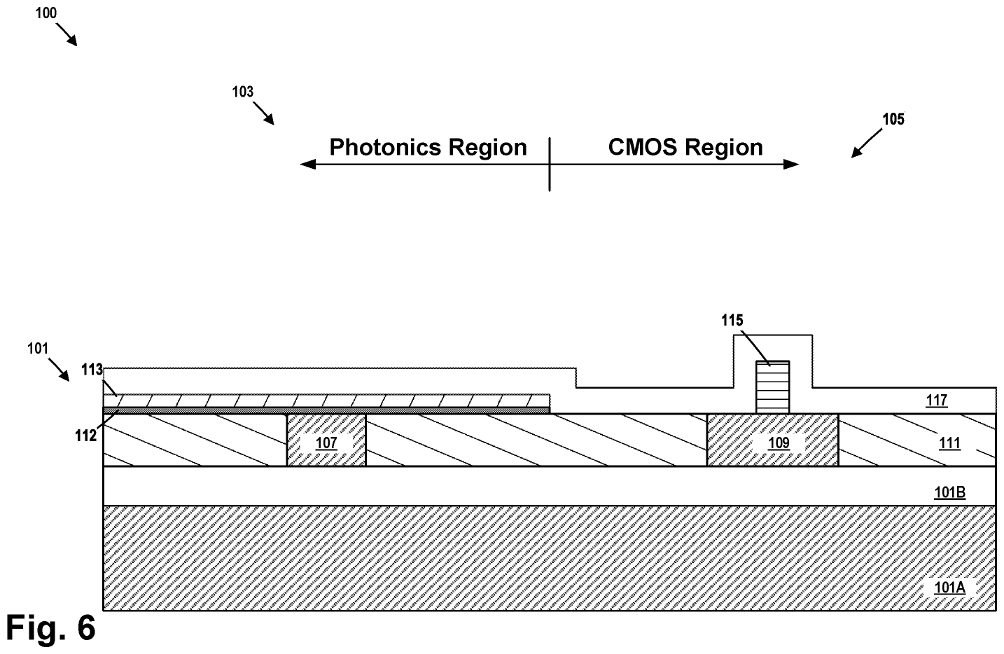

As shown in FIG. 6, at some point during the process of forming CMOS-based circuits in the CMOS region 105, a layer of silicon nitride 117 with a thickness of about 20-150 nm was formed in both the photonic region 103 and the CMOS region 105. The layer of silicon nitride 117 may be formed by performing a blanket deposition process.

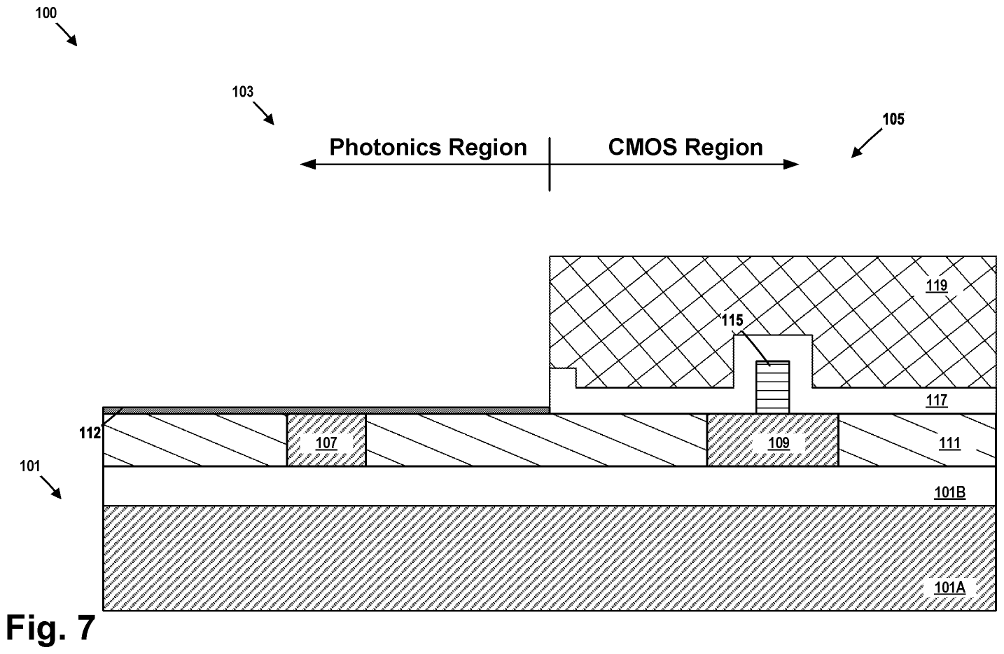

FIG. 7 depicts the IC product 100 after several process operations were performed. First, a patterned etch mask 119 was formed above the layer of silicon nitride 117. The patterned etch mask 119 covers the CMOS region 105 while exposing the photonics region 103 for further processing. The patterned etch mask 119 may take a variety of forms and may be comprised of a variety of different materials e.g., photoresist, OPL, etc. The patterned etch mask 119 may be formed by performing known techniques. Thereafter, an etching process, e.g., an anisotropic etching process, was performed to remove exposed portions of the layer of silicon nitride 117 in the photonics region 103 while leaving the layer of silicon nitride 117 in the CMOS region 105.

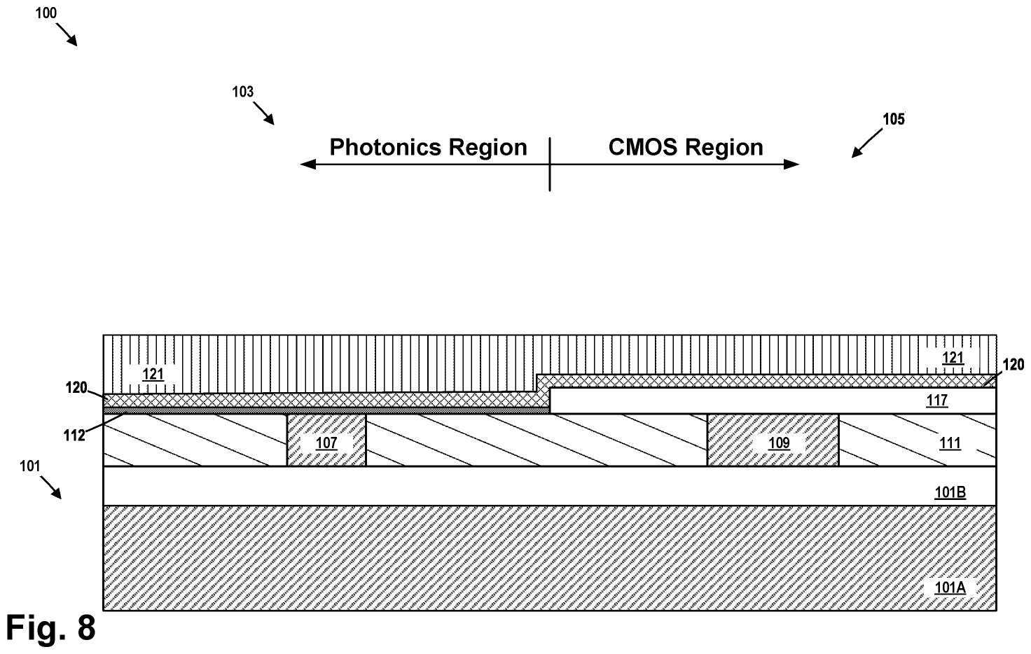

In FIG. 8 and thereafter, the gate structure 115 for the transistor device in the CMOS region 105 will not be depicted so as to simplify the drawings and to facilitate explanation of the subject matter disclosed herein. FIG. 8 depicts the IC product 100 after several process operations were performed. First, a layer of insulating 120 was deposited across the substrate 101 in both the photonics region 103 and the CMOS region 105. Thereafter, a layer of insulating material 121 was formed above the layer of insulating material 120 in both the photonics region 103 and the CMOS region 105. Next, a planarization process, e.g., a CMP and/or an etch-back process, was performed to planarize the upper surface of the layer of insulating material 121. In one particularly illustrative example, the layer of insulating material 121 was formed on and in contact with an upper surface of the layer of insulating material 120. In one illustrative embodiment, the layer of insulating material 120 may be comprised of USG silicon dioxide and it may have a thickness of about 110 nm. In one illustrative embodiment, the layer of insulating material 121 may be comprised of TEOS (tetraethoxysilane) silicon dioxide and it may have a thickness of about 240 nm.

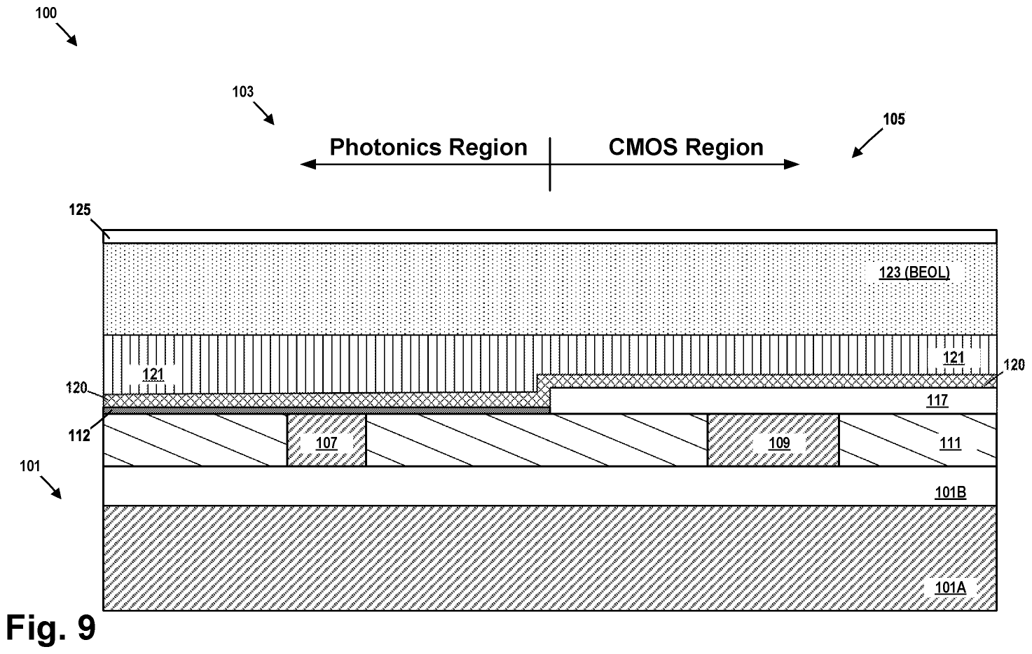

FIG. 9 depicts the IC product 100 after all FEOL (front-end-of-line) processing activities were performed to form all FEOL structures in the CMOS region 105 and after all BEOL (back-end-of-line) processing activities were performed to form all BEOL structures 123 in the CMOS region 105. No attempt has been made in FIG. 9 to show the individual semiconductor devices, e.g., transistors, capacitors, resistors, etc., that are part of the FEOL structures in the CMOS region 105. Moreover, no effort has been made to show individual BEOL structures 123 in the CMOS region 105, e.g., the individual conductive lines (not shown), the individual conductive vias (not shown), the individual layers of insulating material (not shown) and the individual etch stop layers (not shown) that are part of the BEOL structures 123 in the CMOS region 105. In IC products that include both optical components and CMOS-based integrated circuits, the photonics region 103 is substantially free of individual conductive lines and individual conductive vias similar to those formed in the CMOS region 105. However, the various layer of insulating material and etch stop layers that were formed in the CMOS region 105 will also be formed in the photonics region 103. Also depicted in FIG. 9 is a capping layer 125, e.g., a layer of silicon nitride, that is formed above the BEOL materials and structures formed on the product 100.

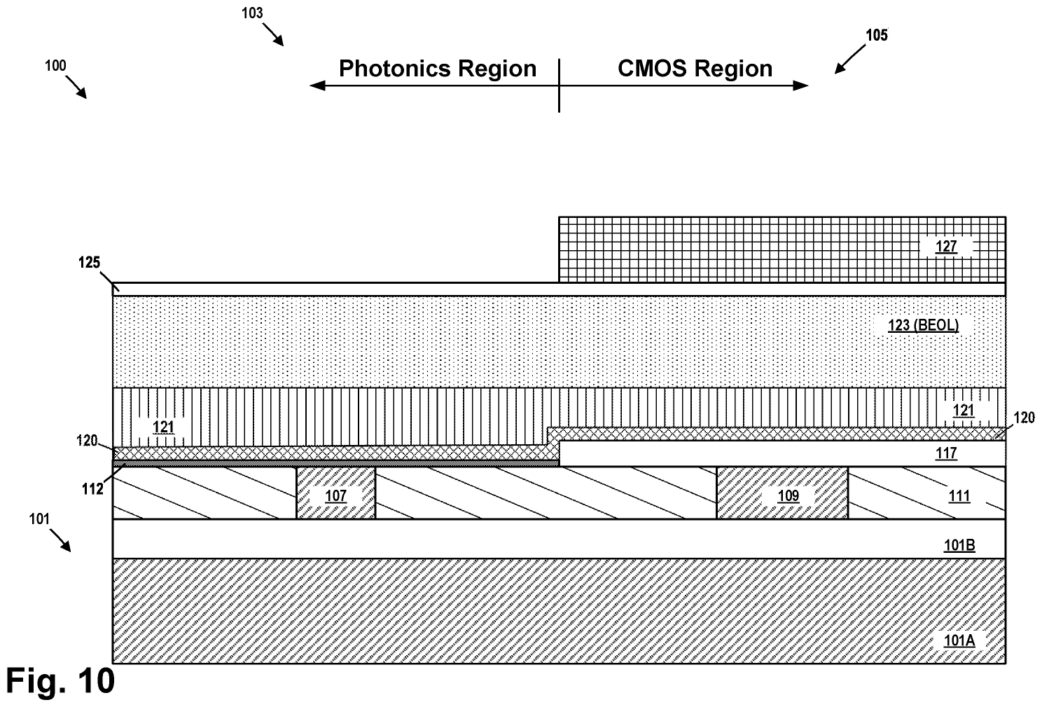

FIG. 10 depicts the IC product 100 after a patterned etch mask 127 was formed above the capping layer 125. The patterned etch mask 127 covers the CMOS region 105 while exposing the photonics region 103 for further processing. The patterned etch mask 127 may take a variety of forms and may be comprised of a variety of different materials e.g., photoresist, OPL, etc. The patterned etch mask 127 may be formed by performing known techniques.

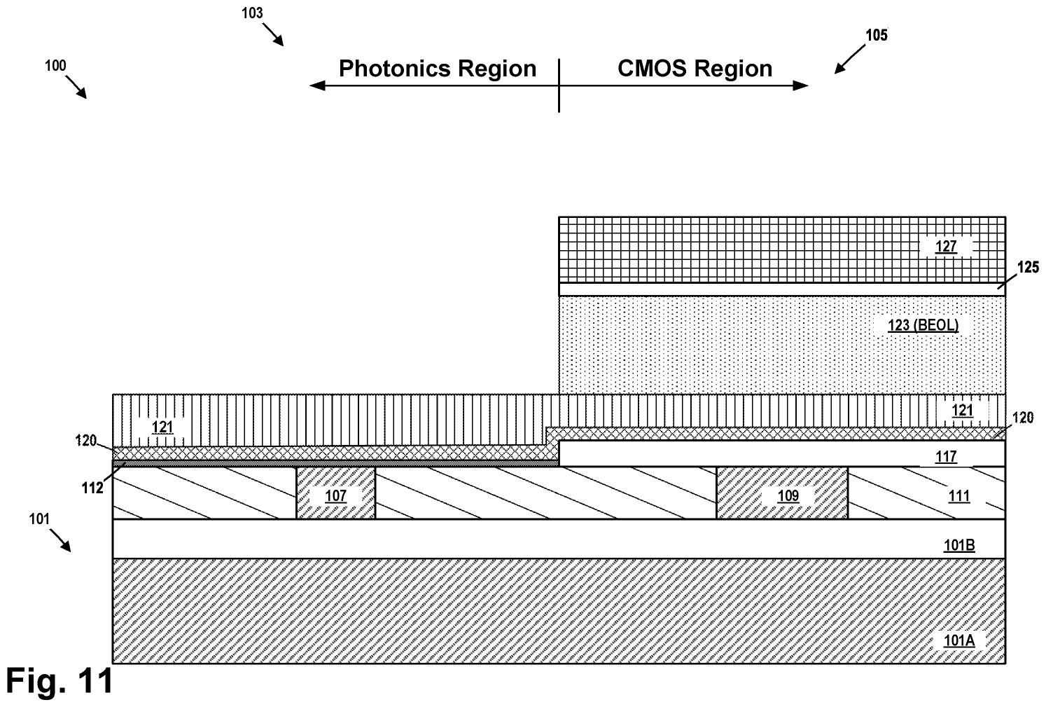

FIG. 11 depicts the IC product 100 after an etching process, e.g., an anisotropic etching process, was performed to remove exposed portions of the capping layer 125 and the BEOL layers of insulating material and the BEOL etch stop layers 123 in the photonics region 103. As depicted, this etching process stops on or within the layer of insulating material 121. In other embodiments, the etching process may stop on or within the layer of insulating material 120. That is, the unique combination of the insulating materials 120, 121 provides an effective means to prevent exposure of the underlying optical component 107 when the etching process is performed to remove the BEOL layers of insulating material and the BEOL etch stop layers 123 in the photonics region 103. Absent the presence of the insulating materials 120, 121, the optical component 107 may be damaged when the etching process is performed to remove the BEOL materials 123 positioned in the photonics region 103.

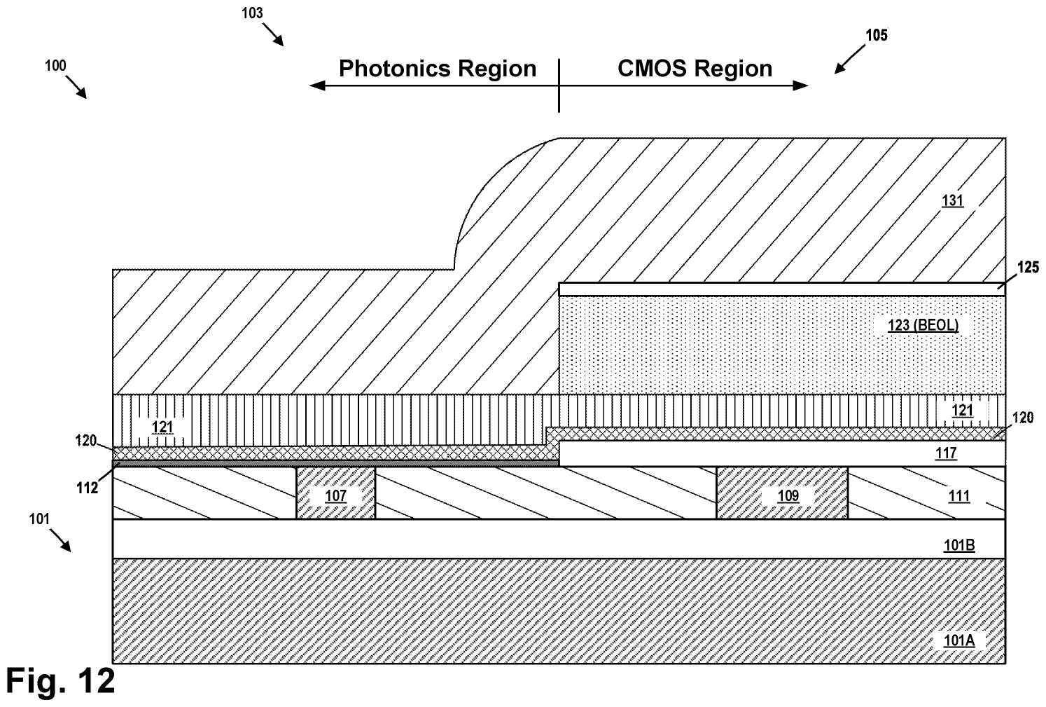

FIG. 12 depicts the IC product 100 after several process operations were performed. First, the patterned etch mask 127 was removed. Next, a layer of insulating material 131, e.g., a layer of TEOS (tetraethoxysilane) silicon dioxide, was deposited across the substrate 101 in both the photonics region 103 and the CMOS region 105. The layer of insulating material 131 was formed to sufficient thickness such that it overfills the opening in the photonics region 103 formerly occupied by the BEOL materials 123 in the photonics region 103.

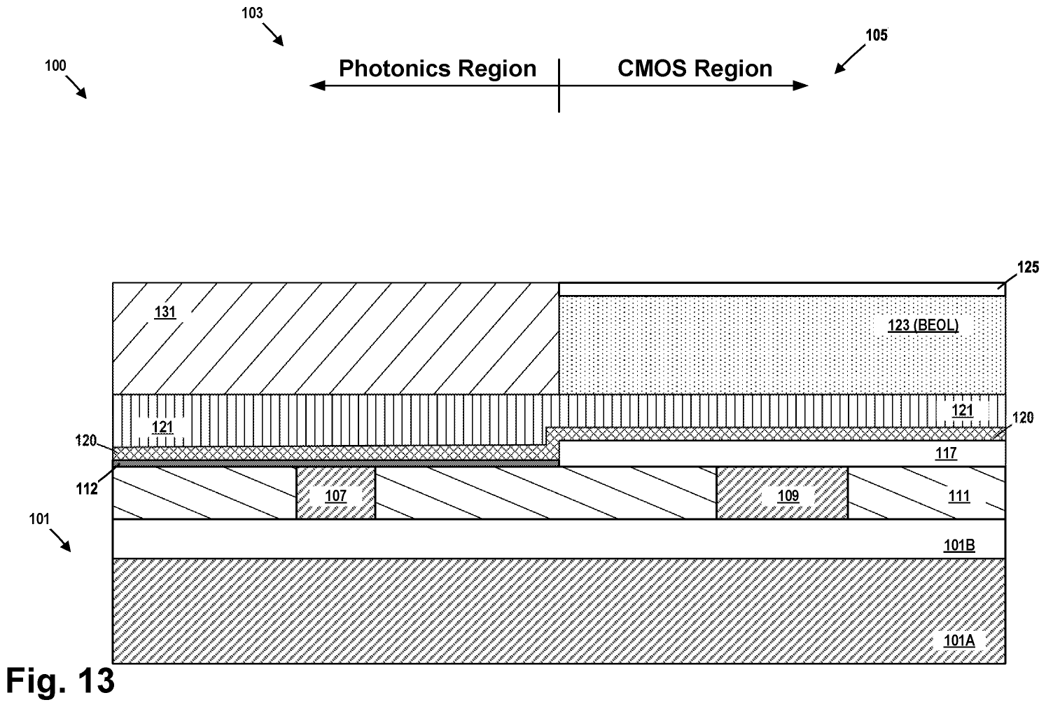

FIG. 13 depicts the IC product 100 after a planarization process, e.g., CMP and/or etch back process, was performed to remove portions of the layer of insulating material 131 above the CMOS region 105 while leaving the layer of insulating material 131 in the photonics region 103.

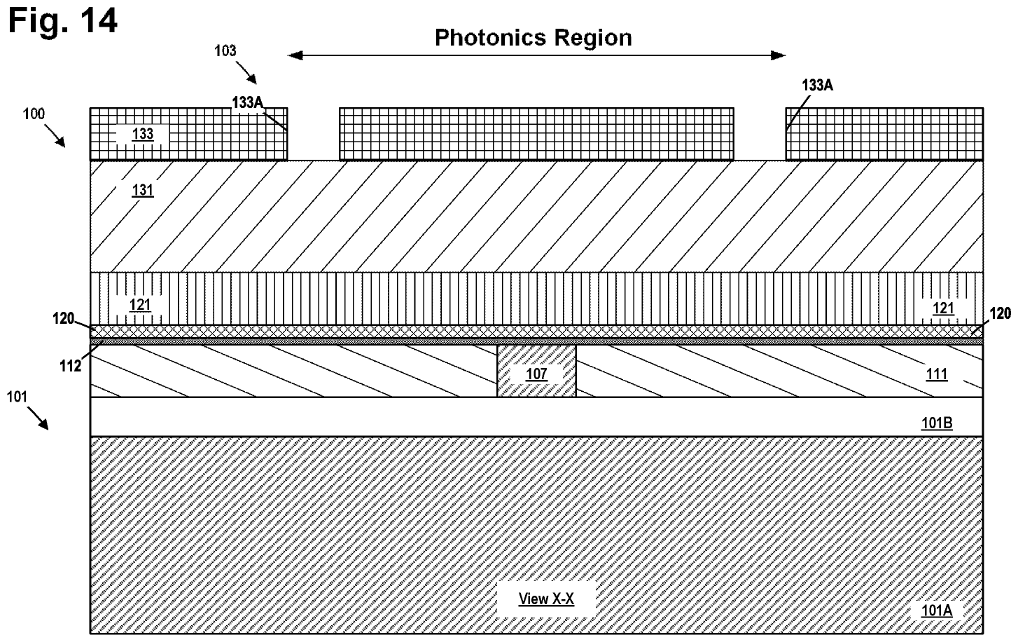

FIGS. 14-19 will now focus on just the photonics region 103 of the IC product 100. The CMOS region 105 of the IC product will be masked or protected during the following process operations directed to the formation of an illustrative V-groove in the base semiconductor layer 101A at locations where a fiber optics cable (not shown) will be operatively coupled to the photonics region 103 of the IC product 100.

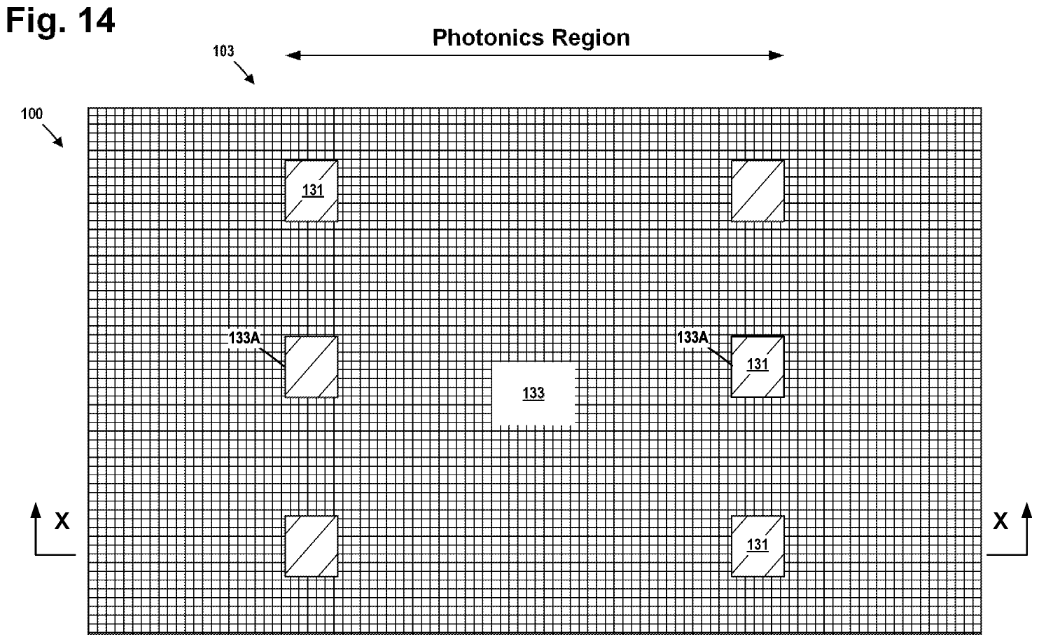

FIG. 14 (a cross-sectional view) and FIG. 15 (a plan view) depict the IC product 100 after a patterned etch mask 133 was formed on the IC product 100. The patterned etch mask 133 comprises a plurality of openings 133A (six depicted by way of example only—see FIG. 15) positioned above the photonics region 103. The patterned etch mask 133 covers the CMOS region 105 (not shown). The patterned etch mask 133 may take a variety of forms and may be comprised of a variety of different materials e.g., photoresist, OPL, etc. The patterned etch mask 133 may be formed by performing known techniques.

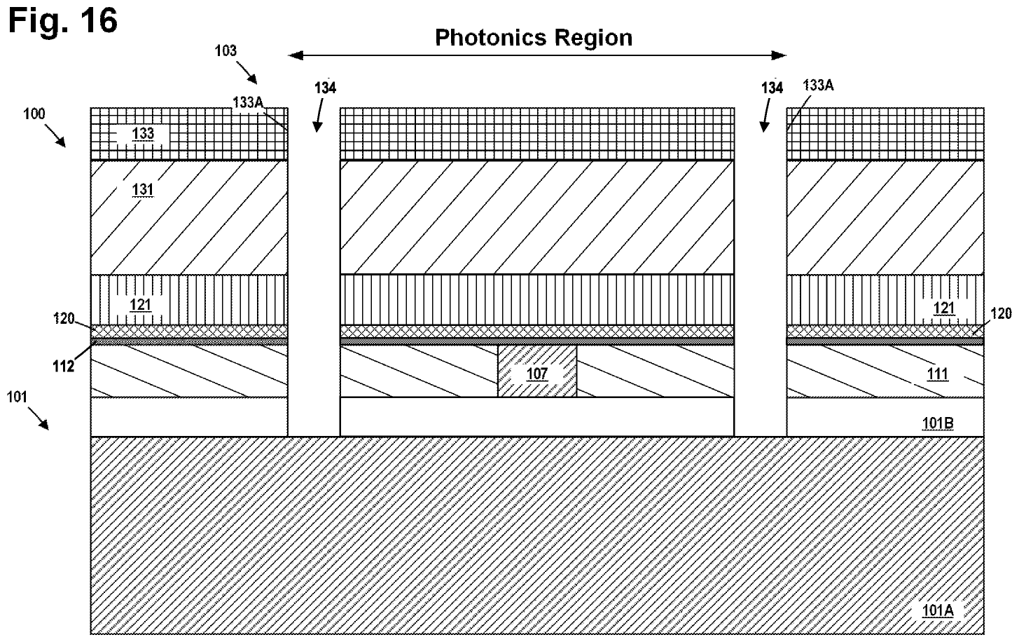

FIG. 16 depicts the IC product 100 after one or more etching processes, e.g., an anisotropic etching process, were performed to remove exposed portions of the layers 131, 121, 120, 112, 111 and the buried insulation layer 101B. This process operation defines a plurality of openings 134 that expose portions of the base semiconductor layer 101A.

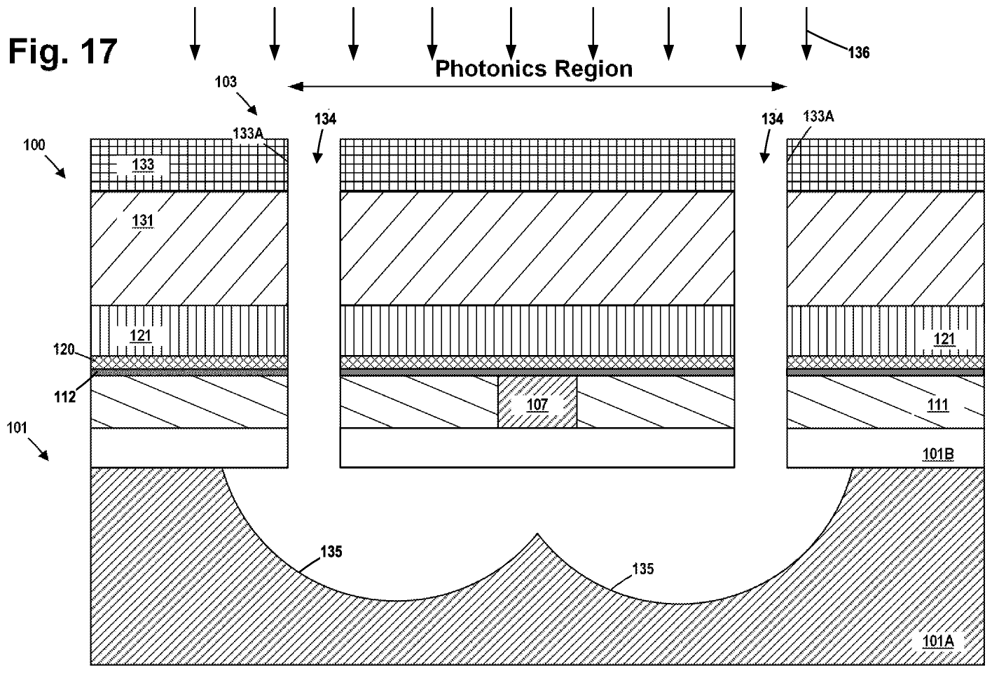

FIG. 17 depicts the IC product 100 after, in accordance with one illustrative process flow, an initial wet isotopic etching process 136 was performed through the openings 134 to form connected recesses 135 in the base semiconductor layer 101A. In one illustrative example where the base semiconductor layer 101A comprises silicon, the etching process 136 may be performed using SF6 as an etchant.

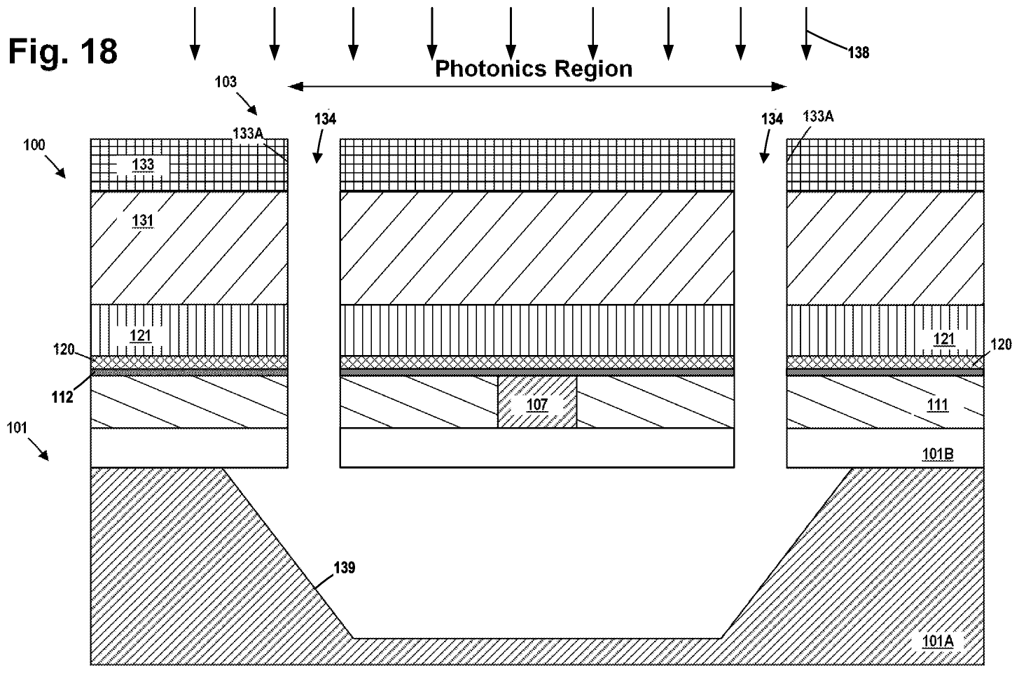

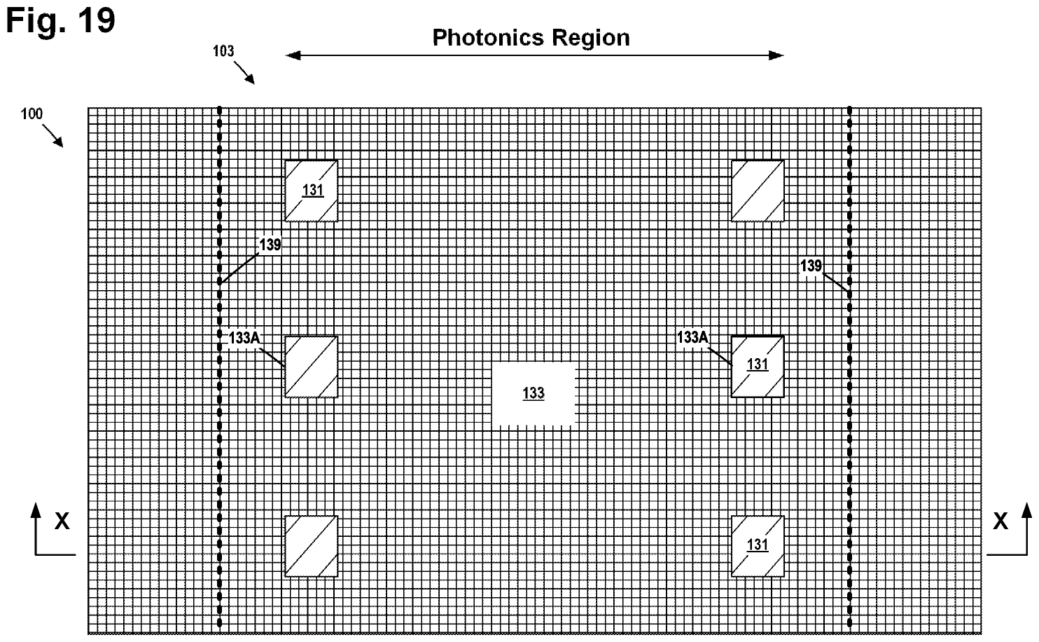

FIG. 18 (a cross-sectional view) and FIG. 19 (a plan view) depict the IC product 100 after another etching process 138, e.g., a wet etching process, was performed through the openings 134 to form the final V-groove 139 in the base semiconductor layer 101A. In one illustrative example where the base semiconductor layer 101A comprises silicon, the etching process 138 may be performed using TMAH as an etchant. This etching process 138 is a crystallographic etch. The configuration of the V-groove 139 shown in FIG. 18 results from the crystallographic orientation of the material of the base semiconductor layer 101A. The outer edges of the V-groove 139 are shown in dashed lines in FIG. 19. After completion of the operations shown in FIGS. 18 and 19, a fiber optics cable (not shown) may be positioned in the V-groove 139 and secured therein by a curable epoxy (or like material) that is introduced into the V-groove 139 via the openings 134 and allowed to cure. The curable epoxy may substantially fill the openings 134.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Note that the use of terms, such as “first,” “second,” “third” or “fourth” to describe various processes or structures in this specification and in the attached claims is only used as a shorthand reference to such steps/structures and does not necessarily imply that such steps/structures are performed/formed in that ordered sequence. Of course, depending upon the exact claim language, an ordered sequence of such processes may or may not be required. Accordingly, the protection sought herein is as set forth in the claims below.

1. A device, comprising:
a semiconductor-on-insulator (SOI) substrate, the SOI substrate comprising a base semiconductor layer, a buried insulation layer positioned above the base semiconductor layer and an active semiconductor layer positioned above the buried insulation layer;
a V-groove in the base semiconductor layer, the V-groove being adapted to have a fiber optics cable positioned therein;
an optical component positioned above the V-groove and above the buried insulation layer;
a first layer of silicon dioxide positioned above the optical component;
a second layer of silicon dioxide positioned on and in contact with the first layer of silica dioxide; and
a third layer of silicon dioxide positioned on and in contact with the second layer of silicon dioxide.

2. The device of claim 1, wherein the active semiconductor layer and the base semiconductor layer comprise silicon and the buried insulation layer comprises silicon dioxide.

3. The device of claim 1, further comprising a fourth layer of silicon dioxide positioned between the optical component and the first layer of silicon dioxide.

4. The device of claim 1, wherein the optical component comprises one of a waveguide, a light coupler or a photodetector.

5. The device of claim 1, wherein the first layer of silicon dioxide comprises USG (undoped silicate glass) silicon dioxide, the second layer of silicon dioxide comprises TEOS (tetraethoxysilane) silicon dioxide and the third layer of silicon dioxide comprises TEOS (tetraethoxysilane) silicon dioxide.

6. The device of claim 3, wherein the first layer of silicon dioxide is positioned on and in contact with the fourth layer of silicon dioxide and wherein the fourth layer of silicon dioxide comprises USG silicon dioxide.

7. The device of claim 1, wherein the first layer of silicon dioxide comprises TEOS (tetraethoxysilane) silicon dioxide and it has a thickness of about 110 nm and wherein the second layer of silicon dioxide comprises TEOS (tetraethoxysilane) silicon dioxide and it has a thickness of about 240 nm.

8. The device of claim 3, wherein the fourth layer of silicon dioxide is positioned on and in contact with an upper surface of the optical component.

9. The device of claim 1, further comprising a photonics region and a CMOS region above the buried insulation layer, wherein the optical component is positioned in the photonics region and wherein the CMOS region comprises CMOS-based integrated circuits.

10. A device, comprising:
a semiconductor-on-insulator (SOI) substrate, the SOI substrate comprising a base semiconductor layer, a buried insulation layer positioned above the base semiconductor layer and an active semiconductor layer positioned above the buried insulation layer;
a V-groove in the base semiconductor layer, the V-groove being adapted to have a fiber optics cable positioned therein;
an optical component positioned above the V-groove and above the buried insulation layer;
a first layer of silicon dioxide comprising USG (undoped silicate glass) silicon dioxide positioned above the optical component, wherein the first layer of silicon dioxide has a thickness of about 110 nm;
a second layer of silicon dioxide comprising TEOS (tetraethoxysilane) silicon dioxide positioned on and in contact with the first layer of silicon dioxide, wherein the second layer of silicon dioxide has a thickness of about 240 nm; and
a third layer of silicon dioxide comprising TEOS (tetraethoxysilane) silicon dioxide positioned on and in contact with the second layer of silicon dioxide.

11. The device of claim 10, further comprising a fourth layer of silicon dioxide positioned between the optical component and the first layer of silicon dioxide, the fourth layer of silicon dioxide comprising USG silicon dioxide.

12. The device of claim 11, wherein the first layer of silicon dioxide is positioned on and in contact with the fourth layer of silicon dioxide.

13. The device of claim 12, wherein the fourth layer of silicon dioxide is positioned on and in contact with an upper surface of the optical component.

14. The device of claim 10, further comprising a photonics region and a CMOS region above the buried insulation layer, wherein the optical component is positioned in the photonics region and wherein the CMOS region comprises CMOS-based integrated circuits.

15. A method, comprising:
forming a CMOS-based integrated circuit above a semiconductor-on-insulator (SOI) substrate in a CMOS region and forming an optical component above the SOI substrate in a photonics region;
forming a first layer of silicon dioxide above the SOI substrate in both the CMOS region and the photonics region, the first layer of silicon dioxide being positioned above the optical component;
forming a first layer of silicon nitride above the first layer of silicon dioxide in both the CMOS region and the photonics region;
forming a second layer of silicon nitride in the CMOS region and above the first layer of silicon nitride in the photonics region;
removing the first and second layers of silicon nitride from the photonics region;
forming a second layer of silicon dioxide in both the CMOS region and the photonics region;
forming a third layer of silicon dioxide above the second layer of silicon dioxide in both the CMOS region and the photonics region;
forming BEOL (back-end-of-line) layers of insulating material and etch-stop layers in both the CMOS region and the photonics region;
performing an etching process to remove the BEOL layers of insulating material and etch-stop layers from above the photonics region while leaving the BEOL layers of insulating material and etch-stop layers in position in the CMOS region, wherein the etching process stops on or within the second or third layers of silicon dioxide; and
forming a fourth layer of silicon dioxide in the photonics region.

16. The method of claim 15, wherein forming the second layer of silicon dioxide comprises forming a layer of USG (undoped silicate glass) silicon dioxide and wherein forming the third layer of silicon dioxide comprises forming a layer of TEOS (tetraethoxysilane) silicon dioxide.

17. The method of claim 16, wherein forming the fourth layer of silicon dioxide comprises forming a layer of TEOS (tetraethoxysilane) silicon dioxide.

18. The method of claim 15, wherein the SOI substrate comprises a base semiconductor layer, a buried insulation layer positioned above the base semiconductor layer and an active semiconductor layer positioned above the buried insulation layer and wherein the method further comprises:
forming a plurality of openings that extend through at least the first, second, third and fourth layers of silicon dioxide and expose an upper surface of the base semiconductor layer; and
performing at least one etching process through the plurality of openings to form a V-groove in the base semiconductor layer, the V-groove being adapted to have a fiber optics cable positioned therein.

19. The method of claim 16, wherein forming the first layer of silicon dioxide comprises forming the first layer of silicon dioxide on and in contact with an upper surface of the optical component.

20. The method of claim 16, wherein forming the second layer of silicon dioxide comprises forming the second layer of silicon dioxide on and in contact with an upper surface of the first layer of silicon dioxide, wherein forming the third layer of silicon dioxide comprises forming the third layer of silicon dioxide on and in contact with an upper surface of the second layer of silicon dioxide and wherein forming the fourth layer of silicon dioxide comprises forming the fourth layer of silicon dioxide on and in contact with an upper surface of the third layer of silicon dioxide.
